(19) United States
(12) Patent Application Publication
(10) Pub. No.: US 2009/0116207 A1
(43) Pub. Date: May 7, 2009

(54) Method for micro component self-assembly

(76) Inventors: Samuel Long Yak Lim, Singapore (SG); Yue Ying Ong, Singapore (SG); Liling Yan, Singapore (SG); Vaidyanthan Kripesh, Singapore (SG); Srinivasa Rao Vempati, Singapore (SG); Ebin Liao, Singapore (SG)

Correspondence Address: JACOBSON HOLMAN PLLC, 400 SEVENTH STREET N.W., SUITE 600, WASHINGTON, DC, 20004, US

(21) Appl. No.: 11/979,544

(22) Filed: Nov. 5, 2007

(51) Int. Cl. H05K 7/02; H05K 3/30

(52) U.S. Cl. 361/807; 29/832

(57) ABSTRACT

A method for micro-component self-assembly is disclosed. An embodiment self-assembly method provides a substrate with an interconnect, and a micro-device having a corresponding interconnect that is arranged for engagement with the interconnect of the substrate during the self-assembly process. A method for fabricating a micro-device for micro-component self-assembly with a substrate and a method for fabricating a substrate for micro-component self-assembly with a micro-device are also disclosed.

### FIELD OF THE INVENTION

This invention relates generally to the field of creating micro devices and micro components through self assembly processes and more particularly to a method and apparatus for orientating self-assembly of micro devices and substrates in the formation of micro components.

### BACKGROUND OF THE INVENTION

Over the past decade, dramatic changes have taken place in silicon device manufacturing, integrated circuit (IC) packaging and systems integration. Silicon devices have been manufactured at the micron feature size, while wafer fabrication and IC packaging and system integration has traditionally been carried out independently. Over this period, each of these areas has developed sustainable technology and market. Disciplines in device and IC packaging have begun to cross over, and chip and package co-design has been necessitated. Assembly of ultra small devices and system integration now require joint consideration and go hand in hand. One application where this has arisen is in the application of bio-medical and disposable electronic devices as these systems require miniaturized modules that are produced in large volumes. To meet these system and device challenges, new innovative processes and upstream technologies are required, especially where a large volume of tiny components needs to be assembled in a low cost and effective way.

Self assembly of micro devices is seen as one of the methods to carry out low cost parallel batch assembly of devices. In recent years, many parallel self-assembly techniques have been developed. Such self-assembly techniques can generally be classified into four categories, namely fluidic shape-directed self-assembly, capillary-driven self-assembly, electrostatically driven self-assembly and magnetically assisted self-assembly. Presently the self assembly process requires complex process steps and increased processing time when compared with non self assembly techniques. For example, fluidic shape-directed self-assembly requires special treatment of the surface and also involves liquid and other medium to enhance the assembly of devices.

Therefore, there is a need to address and alleviate some of these issues associated with previous self assembly techniques and realize a cost effective self assembly method.

### SUMMARY

In accordance with an aspect of the invention a method for micro-component self-assembly comprises providing a substrate having receiving means for receiving a microdevice and an interconnect for electrically connecting with micro-device; introducing a micro-device into the receiving means of the substrate, the micro-device having a corresponding interconnect for electrically connecting with the substrate; agitating the substrate for orientating the micro-device to engage the interconnect of the substrate and the corresponding interconnect of the micro-device; and electrically connecting the micro-device with the substrate.

In accordance with an aspect of the invention a method for fabricating a micro-device for micro-component self-assembly with a substrate, the method comprises providing a wafer having a surface for supporting the fabrication of the micro-device; depositing and patterning a conductive material layer on the surface of the wafer for connecting an interconnect with another interconnect; depositing and patterning an insulating material layer to form a shape of the interconnect; depositing a conductive material to form the interconnect of the micro-device, the interconnect having a shape corresponding with the interconnect of a substrate; and removing the insulating material for engagement of the interconnect of the micro-device with the interconnect of the substrate.

In accordance with an aspect of the invention a method for fabricating a substrate for micro-component self-assembly with a micro-device, the method comprises providing a substrate for fabrication of the interconnect of the substrate for engagement with a corresponding interconnect with the micro-device; depositing and patterning a first layer of nonconductive material for forming the interconnect of the substrate; depositing a conducting layer for electrically connecting the interconnects of the substrate and the micro-device; depositing and patterning a second layer of nonconductive material; and removing the second layer of nonconductive material for engagement of the interconnect of the substrate with the interconnect of the micro-device.

### BRIEF DESCRIPTION OF THE DRAWINGS

In order that embodiments of the invention may be fully and more clearly understood by way of non-limitative example from the following description taken in conjunction with the accompanying drawings in which like reference numerals designate similar or corresponding elements, regions and portions, and in which:

FIG. 1A-G illustrates a self assembly process of micro-component in accordance with an embodiment of the invention;

FIG. 2A-H illustrates a process of plating shaped interconnects in accordance with an embodiment of the invention;

FIG. 3A-E illustrates a process of creating a cavity and interconnects for an assembly process in accordance with an embodiment of the invention;

FIG. 4A-C shows a picture or design of a silicon die with pin in accordance with an embodiment of the invention;

FIG. 5A-C shows pictures of respective cavity in a substrate for receiving the corresponding pins shown in FIGS. 4A and 4B in accordance with an embodiment of the invention;

FIG. 6 is a graph showing the self-assembly yield in accordance with an embodiment of the invention;

FIG. 7 is a flow chart showing a method of micro-component self-assembly in accordance with an embodiment of the invention;

FIG. 8 is a flow chart showing a method of forming protrusions in accordance with an embodiment of the invention; and

FIG. 9 is a flow chart showing a method of forming cavities in accordance with an embodiment of the invention.

### DETAILED DESCRIPTION

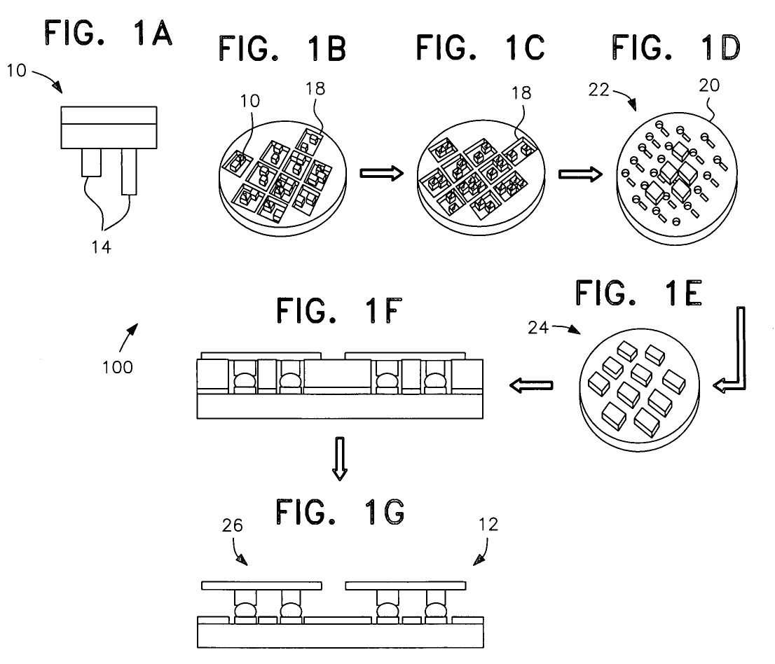

The assembly flow for the fabrication of micro-components 12 is illustrated in FIG. 1A-G. The micro-components 12 comprise a substrate 20 having engaging interconnect means to complimentary engage with engaging interconnect means of a micro-device 10. The micro-devices 10 have shaped interconnects on one surface, and the substrate 20 has correspondingly shaped interconnects to receive the interconnect of the micro-device. In an embodiment the interconnect of the substrate is a cavity, and the interconnect of the micro-device is a protrusion. The substrate 20 may be an organic substrate, silicon substrate, ceramic substrate, glass substrate, BT based substrate, printed circuit board (PCB) or the like. In another embodiment, bond pads (not shown) may be on another surface of the micro-device 10 to form with an additional substrate or PCB (not shown). The protrusions on the micro-components can either be of the same height or have different heights. The substrate 20 and the micro-device 10 have complimentary engaging parts. It will be appreciated that although shaped interconnects are shown for illustrative purposes protruding from the micro-devices 10, the micro-components 12 may be arranged with micro-devices 10 having cavities and the substrate 20 may be arranged with protruding interconnects 14. These micro-devices are randomly distributed on a palletization plate 18 without unique face orientation. An orbital shaker (not shown) is used to provide an external force. The optimal orbital speed for palletization is for example approximately 495 rpm and the time for palletization is approximately 15 minutes for most of the micro-devices 10 to obtain a unique face orientation with the protrusions facing upwards as shown in FIG. 1C. Only a small fraction of the micro-components remain having their protrusions facing downwards at the end of the palletization process.

The micro-devices 10 are transferred to the substrate 20 by ‘flipping’ with the microdevice shaped interconnects by facing the cavities 16 in the substrate. When an external force is applied, the larger circular protrusion engages or falls to mate or lock into the cavities. Then the engaged higher protrusions, pins, IOs or the like 50 of microdevices rotate by the external force, that is for example by the centrifugal forces until the second protrusion such as the shorter protrusion engages or falls to mate or lock into the respective corresponding cavity on the substrate 20. Once engaged, the micro-devices 10 are properly aligned 24 as shown in FIG. 1E. For this process the optimal orbital speed for applying the external force is for example approximately 420 rpm.

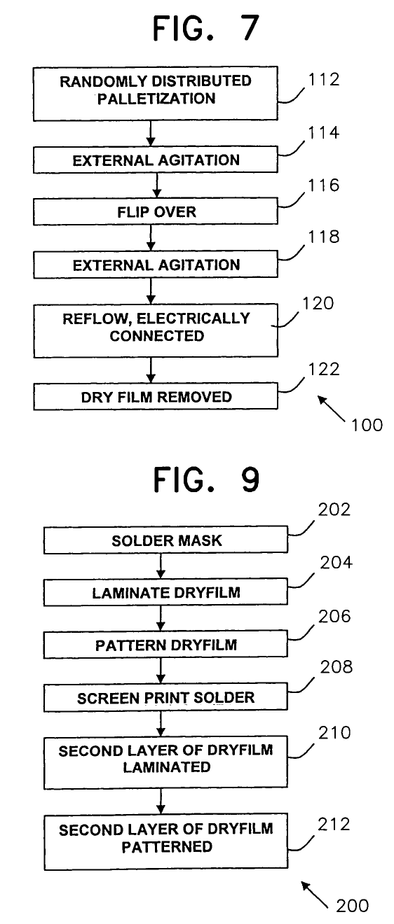

FIG. 1A-G illustrates self-assembly process 100 to form micro-components 12, and FIG. 7 shows a method flow chart of such process in accordance with an embodiment of the invention. FIG. 1A shows a micro-devices 10 with shaped interconnects 14. As shown in FIG. 1B micro-devices 10 are randomly distributed 112 in the cavities 16 of the palletization plate 18 with either the shaped interconnect pins 14 facing upwards or downwards. After external agitation 114, as shown in FIG. 1C, most of the microcomponents 10 have protrusions facing upwards. FIG. 1D shows that the microcomponents are flipped 22 over 116 to the substrate 20. Due to the flipping action, the shaped interconnect pins of the micro-components will be facing the cavities on the substrate. After external agitation 118, the protrusions 14 of the micro-devices 10 will position or engage with the cavities 16 on the substrate and the micro-devices 10 are properly aligned 24 as shown in FIG. 1E. After reflow 120, the micro-components are electrically connected to the substrate wafer.

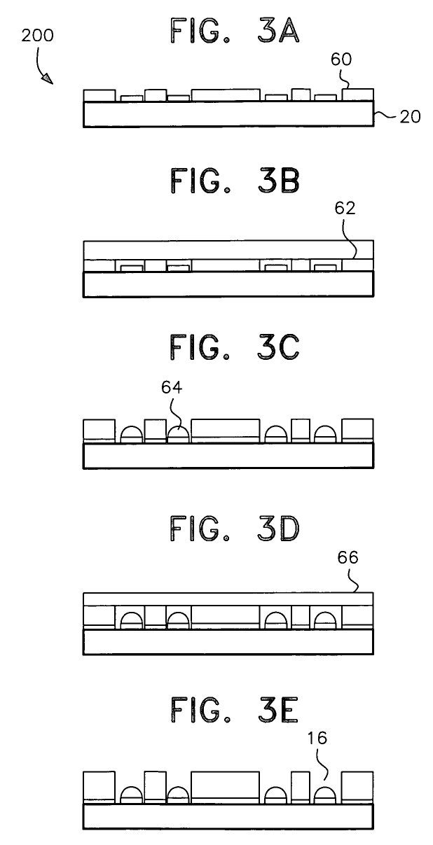

After self-assembly and reflow, the dry film may be removed by immersing the whole wafer into the dry film stripper for 10 min. With the stripping of dry film, daisy chain measurement can be made to check whether the micro devices form good mechanical and electrical joints with the substrate. The dry film layers 62,66 shown in FIGS. 3B, 3D and 3E and discussed in more detail below, may be removed from the substrate 20 for the completed assembly 26 to form the micro-component 12. It will be appreciated that it is not necessary to remove the photoresist material dry film. Singulation of the microcomponents from the substrate may be performed using the conventional dicing process.

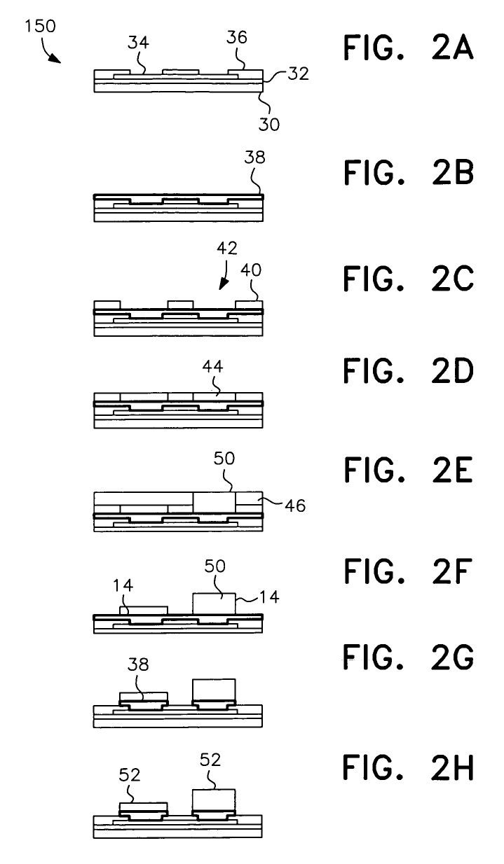

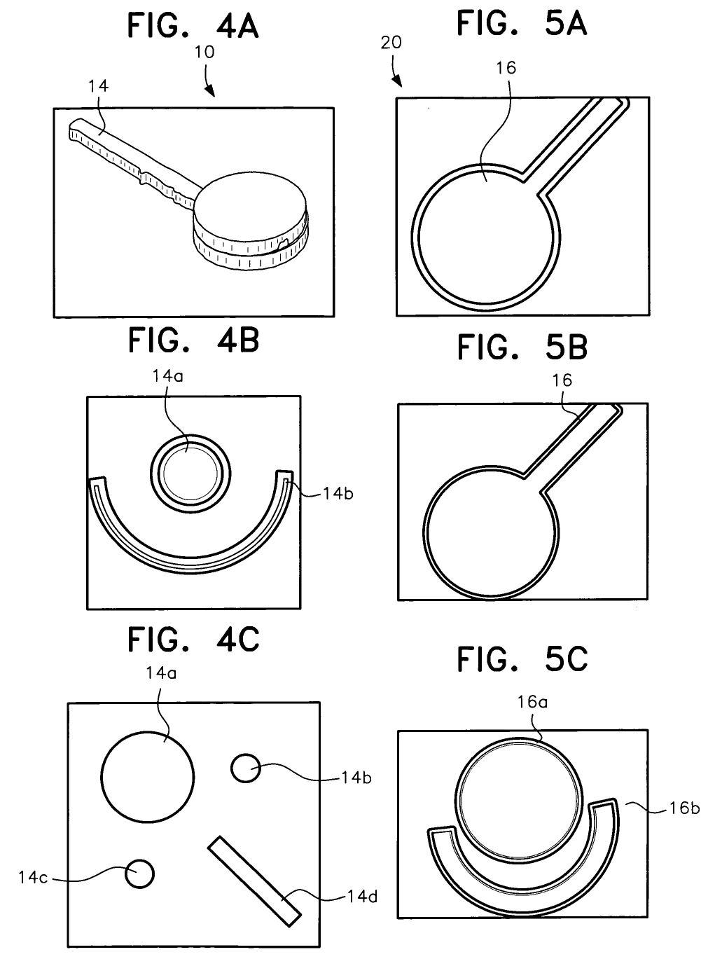

The fabrication of the micro-device 10, for example in accordance with an embodiment of the invention is explained with reference to FIG. 2A-H. The daisy chain chip fabrication starts with the conventional processes with aluminum (Al) metallization layer 34 deposited on silicon dioixde (SiO₂) layer 32 on a wafer 30, such as a silicon substrate, followed by patterning the Al layer 34 with a line connecting between metal pads as shown in FIG. 2A. Wafer 30 may be any wafer such as an organic wafer, silicon wafer, ceramic wafer, glass wafer, BT based wafer, printed circuit board (PCB) or the like. Passivation layer 32 may be any passivation material such as SiO₂, paralene layer, silicon nitride, or the like. Metallization layer 34 may be any metallization material such as Al, Copper (Cu), or the like. A second layer of SiO₂ 36 is deposited and patterned with only a surface of the pads of the metallization layer 34 exposed. Passivation layer 36 may be any passivation material such as SiO₂, paralene layer, silicon nitride, or the like. It will be appreciated that other forms of depositing the materials may be applied such as sputtering, evaporation and the like. For example, under bump metallisation (UBM) for the formation of the metal pads are formed using the sputtering process. The wafer 30 may be thinned down to for example 50 μm or the like by, for example, a mechanical-chemical polishing machine which can be done at other times during the process, for example after these steps, as the first process step, and the like. It will be appreciated that it is not necessary to thin down the wafer. Cu plating forms the shaped interconnects where the height of the Cu pillars can be of the same height or different heights. The shape of the protrusions may also vary, for example the circular pillar with the largest diameter may be the tallest. Next singulation of the chip from the wafer may be performed using the conventional dicing process. The overall process is shown in FIG. 2A-H. FIG. 4A-C shows the picture of a singulated simple daisy chain chip.

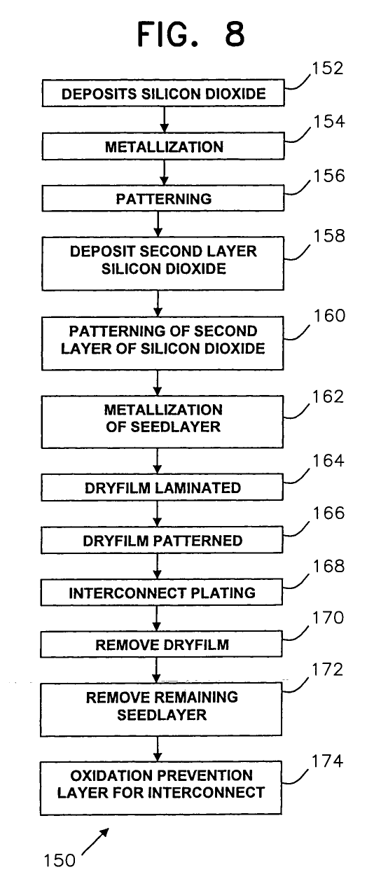

FIG. 2A-H illustrates the process 150 of making protrusions in accordance with an embodiment of the invention, and FIG. 8 shows a method of such process of plating the shaped interconnects 14 having the same heights or different heights are shown. It will be appreciated that in the process of making protrusions having the same height, the step shown in FIG. 2E is omitted. In the first steps as shown in FIG. 2A, the silicon wafer 30 has Al metallization layer 34 deposited 154 on a deposited 152 on a non-conductive layer such as SiO₂ layer 32, followed by patterning 156 of the Al layer 34 with a line of Al connecting between two pads. A second layer of non-conductive material such as SiO₂ layer 36 is deposited 158 and patterned 160 with only the metal pads exposed as shown in FIG. 2B. A metal seedlayer for forming the conductive interconnect protrusion is deposited on the wafer 30 on top of the metal pads and the non-conductive layer. Such a material for the seedlayer may be any conductive material such as metal such as titanium/copper (Ti/Cu) 38 which a Ti layer is first deposited then a Cu layer is deposited on the Ti layer which are sputtered 162 on the wafer 30. It will be appreciated that the seedlayer may be any other UBM layer. In FIG. 2C, a dry film 40 layer is laminated and patterned according to a desired pattern 42 of the required shapes. In FIG. 2D metal, such as Cu, 44 is plated for the initial height of the shaped interconnects. The electrical conductive layer 44 may be any conductive material such as for example Cu, solder, Au or the like. In FIG. 2E, a second layer of dry film 46 is laminated 164,166 and patterned 48 and metal interconnects are plated 168 for the metal pins, such as Cu, that need to be higher. Photoresist layers 40,46 may be any photoresist material such as benzo-cyclobutane, polyimide or the like. It will be appreciated that if all of the pins are arranged to have the same height, this additional step is not required. FIG. 2F shows that dry film layer is stripped away 170. The excess seedlayer 38 is removed 172, for example etched off 172 as shown in FIG. 2G. In FIG. 2H, in an embodiment, a layer to prevent oxidation 52, for example electroless Nickel Au (ENIG), is applied 174 by for example electroplating to prevent the metal or electrical conductive layers forming the pins such as Cu, solder or the like of the protrusion from oxidizing.

In an embodiment, the fabrication of copper protrusions on the micro-device includes a layer of 50 μm dry film is laminated on the wafer at a temperature of 110° C. During photolithography, lights with wavelength of 385 nm and 60 mJ/cm² are used. The patterned dry film is then developed using dry film developer for about 3 minutes to form cavities of shapes such as for example circular and tail protrusions and the like at the dry film layer. Copper electroplating is carried out to form both circular and tail copper protrusions with 50 μm height at both dry film cavities. A second layer of 50 μm dry film is laminated at 110° C. The light energy and wavelength used during photolithography and the dry film developing time may be the same as previous step. There are cavities on the second layer of dry film corresponding to the part of the protrusions that are intended to be taller, for example the circular portions. Copper electroplating is again performed to form only circular protrusions with 50 μm height. The whole wafer is then immersed in the dry film stripper for 10 min. After the removal of both layers of dry film, electroless Ni/Au plating is performed to form a layer of eNiAu on the circular and tail protrusions with 100 μm and 50 μm height respectively. Electroless Ni/Au plating is done to improve the non-wetting problem with the solder in the cavities of the substrate, caused by oxidized copper on the protrusions.

FIG. 4A shows the picture of a silicon die 10 with one pin 14. FIG. 4B shows the picture of a silicon die 10 with two pins. FIG. 4C shows the design of a silicon die 10 with four pins 14a, 14b, 14c, 14d. The protrusions on the micro-components may have same height or different heights as discussed, for example 50 μm to 80 μm. Similarly, the cavities of the substrate may have corresponding depths to receive the protrusions. It will be appreciated that any height may be selected for the protrusions to engage with the substrate. For example, when there are at least two protrusions such as shown in FIG. 4B or FIG. 4C the arc protrusion 14b may have a lower height than the circular protrusion 14a. The circular protrusion allows for the micro-device 10 to lock, whereas the arc protrusion allows for alignment of the micro-device 10 after engagement. It will be appreciated that the micro-device 10 and the substrate 20 may be arranged such that the substrate comprises protrusions and the micro-device 10 comprises corresponding cavities to receive the protrusions extending from the substrate 20.

A fabrication of a substrate is explained in accordance with an embodiment of the invention. The silicon substrate or PCB 20 is laminated with a layer of dryfilm and patterned with cavities that match the chip's pins as shown in FIG. 4. FIGS. 5A-5C shows the results of the patterning.

FIG. 3A-E illustrates the process 200 of forming cavities 16 in accordance with an embodiment of the invention in the substrate, and FIG. 9 shows a method flow chart of such process of creating the cavity for the assembly process. In this embodiment the interconnect cavities are formed in a substrate 20 and form the engaging means for receiving the interconnect protrusions of the micro-device. FIG. 3A shows a raw substrate 20 such as a silicon substrate, PCB, or the like. FIG. 3B shows the substrate 20 is laminated 204 with the first layer of dryfilm 62. FIG. 3C shows the dry film is patterned 206 and solder 64 is applied, such as screen printed or electroplating. FIG. 3D shows a second layer of dry film 66 is laminated 210 by for example spin coating the photoresist material and FIG. 3E shows the second layer of the dry film 66 is patterned 212 to create the cavity 16. Photoresist layers 62,66 may be any photoresist material such as benzo-cyclobutane, polyimide, or the like.

FIG. 5A shows the cavity 16 for 1 pin on a PCB substrate 20. FIG. 5A shows the cavity 16 for 1 pin on a PCB substrate 20. FIG. 5A shows the cavity 16a, 16B for 2 pins on a PCB substrate 20.

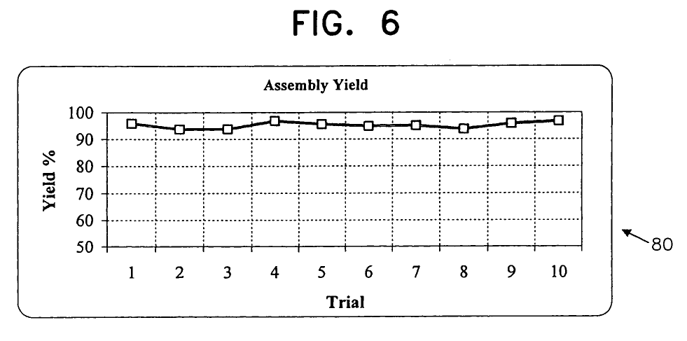

A feature of an embodiment of the invention is obtaining unique orientation using shape matching interconnects. In an embodiment, self-assembly using plated Cu shaped interconnects on dry film has been demonstrated. FIG. 6 shows the self-assembly yield 80 with an average of 95.21% in accordance with an embodiment of the invention. The above process demonstrated more than 1000 micro-components can be assembled onto an 8″ wafer within a short period of time. This in turn shows that the self-assembly can be done at high throughput and low cost.

The self-assembly method provides a method of face and in-plane orientation that does not require a fluid medium or complex chemical and surface treatment such as surface cleaning and/or formation of a self-assembled monolayer. The densely packed receptor sites that are achievable shows that this assembly method may be useful for certain manufacturing purposes, for example LEDs assembly. The high self-assembly yield and gang bonding yield indicated alignment, and the reproducibility of the self-assembly in dry self-assembly method is suitable for many industrial and manufacturing purposes.

While embodiments of the invention have been described and illustrated, it will be understood by those skilled in the technology concerned that many variations or modifications in details of design or construction may be made without departing from the present invention.

1. A method for micro-component self-assembly comprising:
providing a substrate having engaging means for engaging a micro-device and an interconnect for electrically connecting with the micro-device;
complementary engaging a micro-device with the engaging means of the substrate, the micro-device having a corresponding interconnect for engaging with the engaging means and electrically connecting with the substrate;
orientating the micro-device to engage the interconnect of the substrate and the corresponding interconnect of the micro-device; and
electrically connecting the micro-device with the substrate.

2. The method of claim 1 wherein the interconnect of the micro-device is protruding, and the interconnect of the substrate is a cavity.

3. The method of claim 1 wherein the interconnect of the micro-device is protruding, and the interconnect of the micro-device is a cavity.

4. The method of claim 1 wherein there are at least two interconnects on the micro-device, and there is a corresponding interconnect on the substrate for each of the interconnects on the micro-device.

5. The method of claim 1 wherein the interconnects are of different heights.

6. The method of claim 1 wherein the interconnects are of the substantially same height.

7. The method claim 1 wherein the interconnects are of circular shape.

8. The method claim 1 wherein the interconnects are of arc shape.

9. The method of claim 1 wherein there are at least two sets of interconnects.

10. The method of claim 1 wherein substrate is a carrier wafer that forms part of the micro-component structure.

11. The method of claim 1 wherein the orientating is by agitating the substrate to provide an external force to orientate the micro-device and the substrate.

12. A method for fabricating a micro-device for micro-component self-assembly with a substrate, the method comprising:
providing a wafer having a surface for supporting the fabrication of the microdevice;
depositing and patterning a conductive material layer on the surface of the wafer for connecting an interconnect with another interconnect;
depositing and patterning an insulating material layer to form a shape of the interconnect;
depositing a conductive material to form the interconnect of the micro-device, the interconnect having a complementary shape to correspond with the interconnect of a substrate; and
removing the insulating material for engagement of the interconnect of the microdevice with the interconnect of the substrate.

13. The method of claim 12 wherein at least one interconnect is protruding.

14. The method of claim 12 wherein at least one interconnect forms a cavity.

15. The method of claim 12 wherein the micro device has at least two interconnects.

16. The method of claim 12 wherein the interconnects are of the substantially same height.

17. The method of claims 12 wherein an interconnect is of circular shape.

18. The method of claim 12 wherein an interconnect is of arc shape.

19. The method of claim 12 wherein there are at least two sets of interconnects.

20. A method for fabricating a substrate for micro-component self-assembly with a micro-device, the method comprising:
providing a substrate for fabrication of the interconnect of the substrate for engagement with a corresponding interconnect with the micro-device;
depositing and patterning a first layer of nonconductive material for forming the interconnect of the substrate;
depositing a conducting layer for electrically connecting the interconnects of the substrate and the micro-device;
depositing and patterning a second layer of nonconductive material; and
removing the second layer of nonconductive material for engagement of the interconnect of the substrate with the interconnect of the micro-device.

21. A self-assembly micro-component comprising:
a micro-device; and
a substrate having engaging means for engaging the micro-device and an interconnect for electrically connecting with the micro-device;
the micro-device having complementary engaging means to engage with engaging means of the substrate, the micro-device having a corresponding interconnect electrically connected with the substrate.

22. A micro-device for micro-component self-assembly with a substrate, the micro-device comprising:
a wafer having a surface for supporting the fabrication of the micro-device;
a conductive material layer deposited and patterned on the surface of the wafer;
at least two interconnects of a conductive material deposited and patterned on the wafer to form a shape of the interconnect of the micro-device, the interconnect having a complementary shape to correspond with an interconnect of a substrate of the micro-component for engagement of the interconnect of the micro-device with the interconnect of the substrate. each interconnect connected to one another by the conductive material layer.
